(19) United States
(12) Patent Application Publication
(10) Pub. No.: US 2021/0157361 A1
(43) Pub. Date: May 27, 2021

(54) METHOD OF ACHIEVING A DISPLAY SUBSTRATE, DISPLAY SUBSTRATE, AND METAL INTERCONNECTION METHOD

(71) Applicants: BEIJING BOE DISPLAY TECHNOLOGY CO., LTD., Beijing (CN); BOE TECHNOLOGY GROUP CO., LTD., Beijing (CN)

(72) Inventors: Shan Zhang, Beijing (CN); Hong Yang, Beijing (CN); Lianjie Qu, Beijing (CN); Yonglian Qi, Beijing (CN); Hebin Zhao, Beijing (CN); Yun Qiu, Beijing (CN); Chao Liu, Beijing (CN); Zhenhua Lv, Beijing (CN); Yang You, Beijing (CN)

(21) Appl. No.: 17/022,486

(22) Filed: Sep. 16, 2020

(30) Foreign Application Priority Data
Nov. 27, 2019 (CN) 201911182714.8

(51) Int. Cl. G06F 1/16; G02B 1/14; G06F 1/18; B32B 37/00; B32B 37/06

(52) U.S. Cl. CPC G06F 1/1609; G02B 1/14; B32B 2457/20; B32B 37/0053; B32B 37/06; G06F 1/189

(57) ABSTRACT

To construct a display substrate, a first metal connection part is formed on a first surface of a base substrate, extending to a first surface edge region, and a second metal connection part is formed on a second surface of the base substrate opposite to the first surface, extending to a second surface edge region. A flexible film formed on the first surface is patterned to expose a portion of the first surface edge region, aligned with the first metal connection part. A portion of the base substrate covered by the first surface edge region is removed. A portion of the flexible film in the first surface edge region is bent to cover at least a portion of a sidewall of the base substrate. A sidewall metal connection part is formed to electrically connect the first and second metal connection parts, and the flexible film is removed.

### CROSS-REFERENCE TO RELATED APPLICATION

This application claims priority to Chinese Patent Application No. 201911182714.8, filed on Nov. 27, 2019, which is incorporated herein by reference in its entirety.

### TECHNICAL FIELD

The present disclosure relates to the field of display technology, and particularly to a method of achieving a display substrate, a display substrate, and a metal interconnection method.

### BACKGROUND

A substrate is an important component of a display apparatus, and needs to be electrically connected with a driver IC. Therefore, in the related art, a display device and a frame region for electrically connecting the display device and the driver IC are usually arranged on a side of a base substrate of the substrate. With the limitations imposed by a size and a volume of the driver IC itself, the frame region on the substrate has a large area. Especially at present splice screens are mainly used in existing large-size display products, and a width problem of the frame region has particularly become a main factor that limits the splice screen. Thin lines visible to naked eyes formed in the frame region after splicing will bring a poor visual experience to a user.

Therefore, in order to overcome the technical shortcomings existing in the related art, there is a need to provide a method of achieving a display substrate, a narrow-frame display substrate, and a metal interconnection method.

### SUMMARY

According to an aspect of the present disclosure, there is provided a method of achieving a display substrate, the method comprising:

forming, on a first surface of a base substrate, a first metal connection part extending to a first surface edge region, and forming, on a second surface of the base substrate opposite to the first surface, a second metal connection part extending to a second surface edge region, wherein an orthogonal projection of the first surface edge region on a plane where the base substrate is located is aligned with an orthogonal projection of the second surface edge region on the plane, and an orthogonal projection of an end, extending to the first surface edge region, of the first metal connection part on the plane is aligned with an orthogonal projection of an end, extending to the second surface edge region, of the second metal connection part on the plane;

forming a flexible film on the first surface;

patterning the flexible film to expose a portion of the first surface edge region, wherein the exposed portion of the first surface edge region is aligned with the first metal connection part;

removing a portion of the base substrate covered by the first surface edge region;

bending a portion, in the first surface edge region, of the flexible film to cover at least a portion of a sidewall of the base substrate;

forming a sidewall metal connection part on an exposed portion of the sidewall with the bent portion of the flexible film as a mask, to electrically connect the first metal connection part and the second metal connection part; and removing the flexible film.

In some embodiments, the flexible film comprises a dry film.

In some embodiments, bending the portion, in the first surface edge region, of the flexible film to cover at least the portion of the sidewall of the base substrate comprises:

bending the portion, in the first surface edge region, of the flexible film to cover at least the portion of the sidewall of the base substrate and extend onto the second surface.

In some embodiments, forming the flexible film on the first surface comprises:

attaching the dry film onto the first surface of the base substrate with a hot pressing roller.

In some embodiments, patterning the flexible film to expose the portion of the first surface edge region comprises:

irradiating the dry film with ultraviolet rays through a mask; and

removing, with a developing solution, a portion of the dry film shielded by the mask, to expose the portion of the first surface edge region aligned with the first metal connection part.

In some embodiments, forming the sidewall metal connection part on the exposed portion of the sidewall with the bent portion of the flexible film as the mask, to electrically connect the first metal connection part and the second metal connection part comprises:

evaporating a metal on the exposed portion of the sidewall by a magnetron sputtering method with the bent portion of the flexible film as the mask, to form the sidewall metal connection part.

In some embodiments, removing the flexible film comprises:

stripping the dry film by a strongly alkaline solution.

In some embodiments, a display device is disposed on the first surface of the base substrate and a display driver IC is disposed on the second surface of the base substrate opposite to the first surface, such that an electrical signal is provided to the display device through the first metal connection part, and the second metal connection part is electrically connected with the display driver IC.

According to another aspect of the present disclosure, there is provided a display substrate, comprising:

a base substrate;

a first metal connection part formed on a first surface of the base substrate and extending to an edge of the base substrate;

a second metal connection part formed on a second surface of the base substrate opposite to the first surface and extending to the edge of the base substrate; and

a sidewall metal connection part formed on a sidewall of the base substrate, wherein the sidewall metal connection part electrically connects the first metal connection part and the second metal connection part.

In some embodiments, the display substrate further comprises:

a display device formed on the first surface of the base substrate and a display driver IC formed on the second surface of the base substrate opposite to the first surface, wherein an electrical signal is provided to the display device through the first metal connection part, and the second metal connection part is electrically connected with the display driver IC, such that a drive signal is provided to the display device by the display driver IC.

According to yet another aspect of the present disclosure, there is provided a metal interconnection method, comprising:

providing a base substrate, the base substrate comprising: a first metal connection part led out to a first surface edge region of a base substrate; and a second metal connection part led out to a second surface edge region opposite to the first surface edge region, of the base substrate, wherein an orthogonal projection of the first surface edge region on a plane where the base substrate is located is aligned with an orthogonal projection of the second surface edge region on the plane, and an orthogonal projection of an end, extending to the first surface edge region, of the first metal connection part on the plane is aligned with an orthogonal projection of an end, extending to the second surface edge region, of the second metal connection part on the plane;

forming a flexible film on the first surface;

patterning the flexible film to expose a portion of the first surface edge region, wherein the exposed portion of the first surface edge region is aligned with the first metal connection part;

removing a portion of the base substrate covered by the first surface edge region;

bending a portion, in the first surface edge region, of the flexible film to cover at least a portion of a sidewall of the base substrate;

forming a sidewall metal connection part on an exposed portion of the sidewall with the bent portion of the flexible film as a mask, to electrically connect the first metal connection part and the second metal connection part; and

removing the flexible film.

In some embodiments, the flexible film comprises a dry film.

### BRIEF DESCRIPTION OF THE DRAWINGS

Embodiments of the present disclosure will be further described in detail as below in combination with the accompanying drawings.

FIG. 1 is a flow diagram of a method of achieving a display substrate according to an embodiment of the present disclosure;

FIGS. 2a-2k are schematic views showing a display substrate in specific steps of a method of achieving a display substrate according to an embodiment of the present disclosure; and

FIG. 3 is a flow diagram of a metal interconnection method according to an embodiment of the present disclosure.

### DETAILED DESCRIPTION

In order to describe the present disclosure more clearly, a further description of the present disclosure will be made as below with reference to embodiments taken in conjunction with the accompanying drawings. Similar elements are indicated by the same reference signs in the accompanying drawings. It would be appreciated by those skilled in the art that the contents specifically described below are illustrative rather than restrictive, and should not be used to limit the protection scope of the present disclosure.

It should be noted that the term “narrow frame” in the related art refers to the narrow distance between the edge of the image displayed by the display device and the edge of the substrate. In other words, there is a difference in order of magnitude between the width of the image display area and the width of the frame area, such as at least 10:1. It would be appreciated by those skilled in the art that with the continuous development of science and technology, the difference in order of magnitude between the width of the image display area and the width of the frame area will continue to increase.

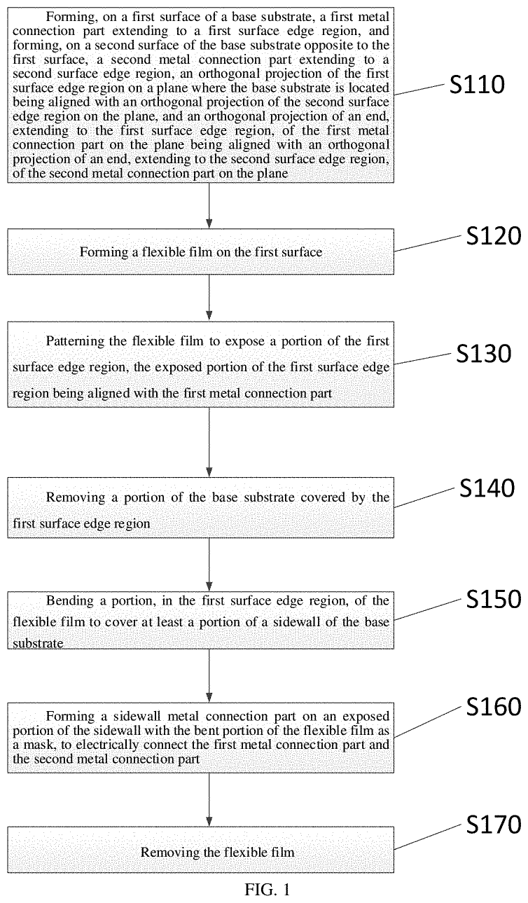

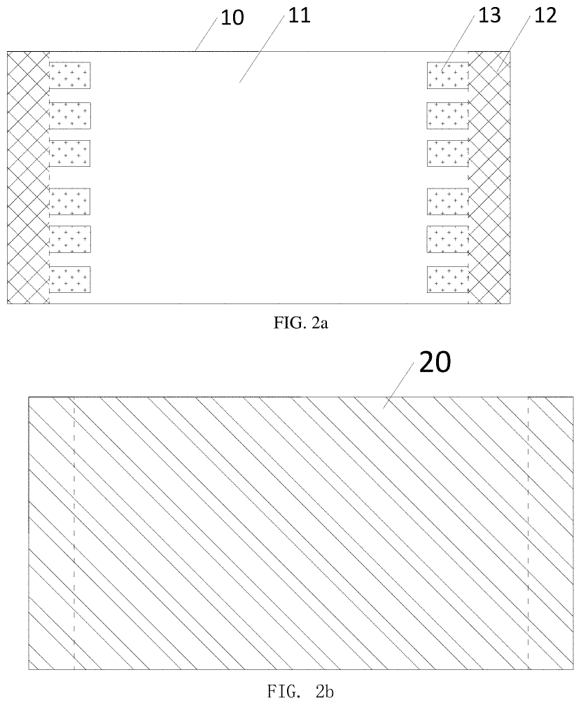

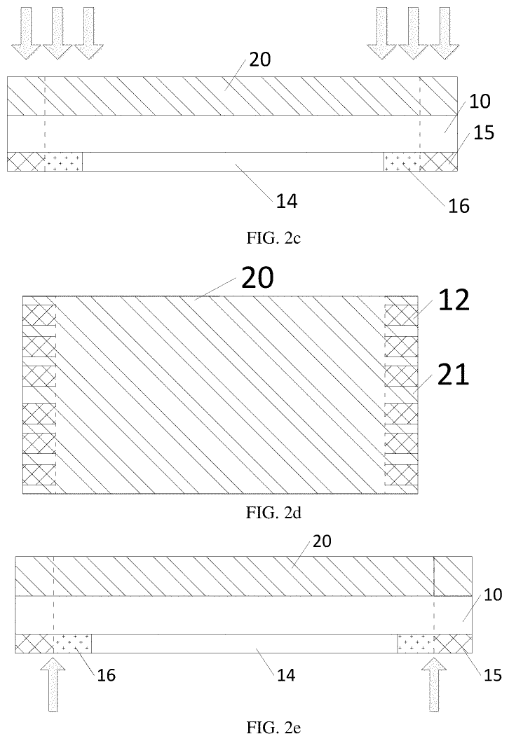

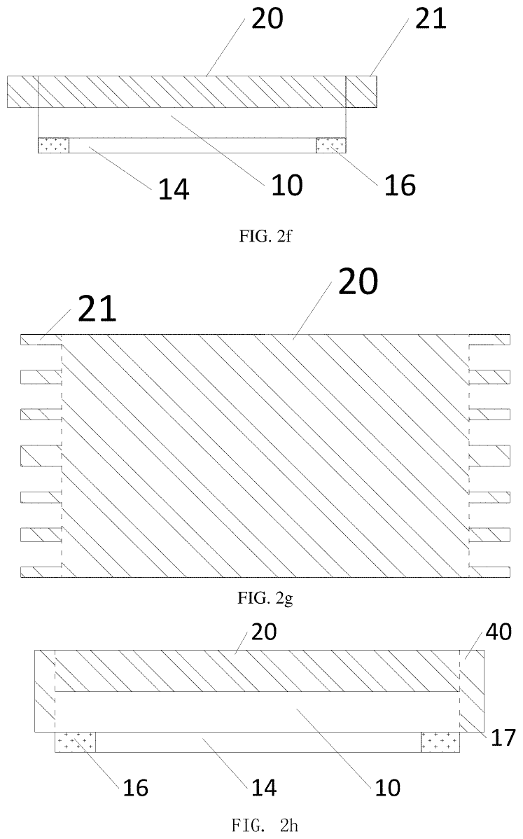

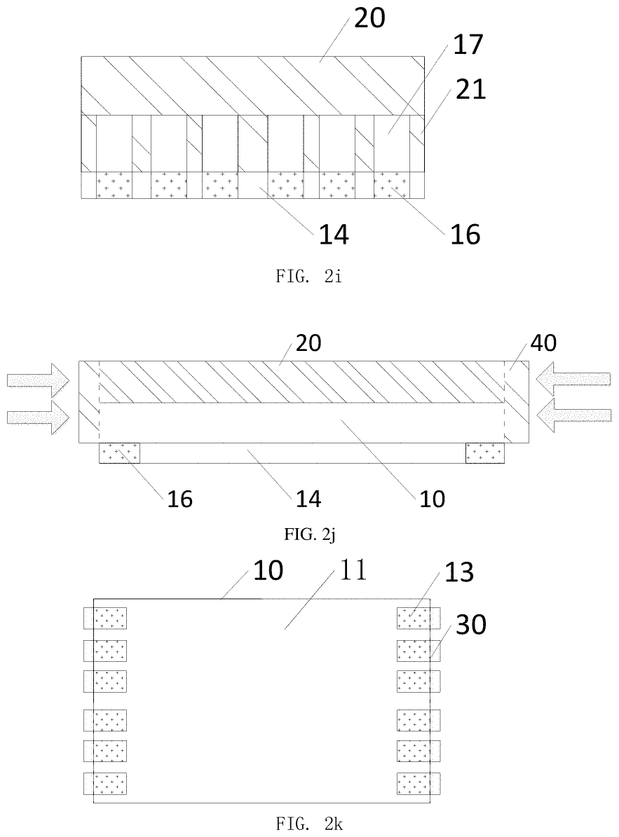

In view of the problems existing in the related art, the present disclosure provides a method of achieving a narrow frame of a display substrate. As shown in FIGS. 1 and 2a-2k. The method includes the following steps.

In a step S110, as shown in FIG. 2a, a first metal connection part 13 extending to a first surface edge region 12 is formed on a first surface 11 of a base substrate 10, and a second metal connection part 16 extending to a second surface edge region 15 is formed on a second surface 14 (as shown in FIG. 2c) of the base substrate 10 opposite to the first surface 11. An orthogonal projection of the first surface edge region 12 on a plane where the base substrate is located is aligned with an orthogonal projection of the second surface edge region 15 on the plane, and an orthogonal projection of an end, extending to the first surface edge region 12, of the first metal connection part 13 on the plane is aligned with an orthogonal projection of an end, extending to the second surface edge region 15, of the second metal connection part 16 on the plane.

An electrical signal is provided to the display device through the first metal connection part 13. For example, the first metal connection part may be connected to an electrode of a thin film transistor (TFT) device or an anode or a cathode of a light emitting device on the base substrate through a via hole. The second metal connection part 16 is electrically connected with the display driver IC.

In a specific example, a material of the base substrate may be glass, indium tin oxide, or the like.

It can be appreciated that the first surface edge region 12 and the first metal connection part 13 are aligned with the second surface edge region 15 and the second metal connection part 16, respectively.

In a step S120, as shown in FIG. 2b, a flexible film 20 is formed on the first surface 11. The flexible film 20 covers the display device on the first surface 11, the first surface edge region 12 (in FIG. 2b, inner edges of the first surface edge region 12 are indicated by dashed lines), and the first metal connection part 13.

The flexible film may be a film made of a photosensitive, bendable, flexible material. In a specific embodiment, the flexible film is a dry film. In the present disclosure, the dry film is a photosensitive material, which is used for transfer of a pattern of a circuit board. In coating, the meaning of the term “dry film” is relative to the wet film. The dry film is a macromolecular compound. The macromolecular compound can undergo polymerization (a reaction process of synthesizing a polymer from monomers) after being irradiated by ultraviolet rays, so as to form a stable substance. The substance is attached onto the surface of the base substrate to achieve the function of blocking electroplating and etching. Usually the dry film is sandwiched between a PE protective layer and a PET protective layer. The PE protective layer and the PET protective layer play only a protective role. The PE protective layer and the PET protective layer need to be removed prior to being pressed and being developed. What is used is the dry film sandwiched between them. The dry film has a certain viscosity and good photosensitivity. The dry film is generally attached onto the surface of the base substrate by bonding, which makes the thickness of the dry film uniform and controllable. When a bent portion is subsequently formed of the dry film, the bent portion has a relatively stable size.

In an optional embodiment, the dry film 20 is attached onto the first surface 11 of the base substrate 10 with a hot pressing roller. Specifically, with a laminator, the dry film 20 is attached onto the first surface 11 of the base substrate 10 with the hot pressing roller while the PE protective layer is removed. Optionally, the hot pressing roller has a hot pressing temperature of 100-120° C. After the dry film 20 is attached onto the first surface 11 of the base substrate 10, it is optionally left to stand for about 2-5 hours to ensure that the dry film is completely attached onto the first surface 11 of the base substrate.

In a specific embodiment, the first surface of the base substrate may be pretreated before the flexible film is formed, mainly to solve problems of surface cleanliness and surface roughness of the first surface, so as to increase the adhesion of the flexible film on the base substrate.

In a step S130, as shown in FIGS. 2c and 2d, the flexible film 20 is patterned to expose a portion of the first surface edge region 12. The exposed portion of the first surface edge region 12 is aligned with the first metal connection part 13.

In a specific example, if the flexible film is, for example, a dry film, then as shown in FIG. 2c, a portion of the dry film 20 which is located on the first surface edge region 12 and which is aligned with the first metal connection part 13 is shielded by a mask, and an unshielded portion of the dry film 20 is irradiated with ultraviolet rays along a direction indicated by the arrows shown in FIG. 2c, so that the dry film 20 forms a stable substance and is attached onto the base substrate 10. A portion of the dry film 20 shielded by the mask is removed with a developing solution, as shown in FIG. 2d. The developing solution may be sodium carbonate solution or other weakly alkaline solutions. The unexposed portion of the dry film 20 is washed away by the developing solution so that the portion of the first surface edge region 12 is exposed to form a bent portion 21, and the exposed portion of the dry film 20 is retained.

In a step S140, a portion of the base substrate covered by the first surface edge region 12 is removed. In an example where the base substrate is made of glass, as shown in FIG. 2e, by a glass cutting device or a glass edging device, the base substrate 10 is cut within an alignment accuracy control range along the positions indicated by the arrows shown in FIG. 2e, thereby cutting away the portions of the base substrate 10 corresponding to the first surface edge region 12 and the second surface edge region 15. The cutting length is equal to a thickness (for example, 500 μm) of the base substrate, so that the bend portion 21 of the flexible film is suspended, as shown in FIGS. 2f-2g.

In a step S150, as shown in FIGS. 2h and 2i, the portion, in the first surface edge region, of the flexible film is bent to cover at least a portion of a sidewall 17 of the base substrate 10.

Specifically, as shown in FIGS. 2h and 2i, the bent portion 21 of the flexible film may be attached onto the portion of the sidewall 17 of the base substrate 10 by using a bonding adhesive. FIG. 2i is a front view of the sidewall of the base substrate. As shown in FIG. 2i, the portion of the sidewall 17 of the base substrate is covered with the bent portion 21 of the flexible film, and an exposed portion of the sidewall 17 corresponds to the first metal connection part 13 and the second metal connection part 16.

In an optional embodiment, the bent portion of the flexible film may also be bent to cover the portion of the sidewall of the base substrate and extend onto the second surface. In other words, the bent portion of the flexible film is bent to cover the second surface. It can be appreciated that the optional embodiment will not affect subsequent formation of a sidewall metal connection part on the exposed portion of the sidewall of the base substrate.

In a step S160, as shown in FIG. 2j, the sidewall metal connection part is formed on the exposed portion of the sidewall with the bent portion of the flexible film as a mask, to electrically connect the first metal connection part and the second metal connection part.

In an optional embodiment, a metal is evaporated on the exposed portion of the sidewall 17 shown in FIG. 2i by a magnetron sputtering method with a covering region 40 as the mask, to form the sidewall metal connection part 30. Specifically, as shown in FIG. 2j, the base substrate 10 is first preheated and cleaned by plasma, so that the bonding force between the side wall metal connection part 30 to be subsequently formed and the sidewall 14 is enhanced. The target material may be a column-shaped target material. In the optional embodiment, with the covering region as the mask, in the process of forming the metal connection parts, sufficient gaps are left between the metal connection parts to avoid short circuit caused by their mutual connection.

In a step S170, the flexible film is removed.

In a specific example, the dry film 20 is stripped by a strongly alkaline solution, to form a narrow-frame substrate. A final structure of the display substrate is shown in FIG. 2k. The first metal connection part 13 is connected with the second metal connection part 16, located on the second surface 14, through the sidewall metal connection part 30.

In a specific example, the strongly alkaline solution may be a sodium hydroxide solution with a concentration of 2% to 3%.

With the method of achieving the narrow frame of the display substrate according to the present embodiment, firstly, the driver IC disposed on the second surface is electrically connected with the display device located on the first surface, which can meet the requirements of the narrow frame of the substrate, so that an ultra-narrow-frame design or a frame-free design of a display panel provided with the substrate can be carried out to effectively improve a user's viewing experience. Further, the inventor of the present application considers that at present the sidewall metal connection part is usually achieved by applying, exposing, and developing a photoresist in the related art. However, the size of the side of the substrate is relatively small and the size and weight of the substrate are relatively large. Therefore, it is difficult to place the substrate vertically. Even if several substrates are placed side by side, there are inevitably gaps between the substrates in the processes of applying, exposing, and developing the photoresist. Hence, metal is easily formed on the front and back of the substrate during an etching process, so that the front and back of the substrate are damaged and even a short circuit is produced, which causes the substrate to be scrapped. However, with the method of achieving the display substrate according to the present disclosure, only the flexible film needs to be removed without needing a metal etching step to form the sidewall metal connection part on the sidewall of the substrate, thereby avoiding the situation where the substrate is damaged by a short circuit that is produced by contamination of the front and back of the substrate and even formation of metal on the front and back of the substrate possibly caused by the metal etching step. Further, the achieving method is simple to operate, has strong operability, is compatible with the production line process, and effectively saves costs. In addition, in the method of achieving the substrate according to the present disclosure, the sidewall metal connection part is formed with the covering region as the mask. Compared with a method in which metal on the sidewall is etched directly by a laser, the achieving method according to the present disclosure can ensure that there are gaps between the metal connection parts with the covering region as the mask, thereby avoiding a short circuit caused by their mutual connection due to formation of metal between the metal connection parts in the process of forming the metal.

It is to be noted that the substrate including only one first surface edge region and only one first metal connection part is illustrated. It would be appreciated by those skilled in the art that in an actual process, the substrate may include two edge regions and two metal connection parts on the same surface, and two edge regions and two metal connection parts on the opposite surface to achieve a unilateral drive, or the substrate may also include four edge regions and four metal connection parts distributed around the display region, and four edge regions and four metal connection parts on the opposite surface to achieve a bilateral drive, which is not further limited in this embodiment.

Another embodiment of the present disclosure further provides a narrow-frame display substrate. As shown in FIG. 2k, the narrow-frame display substrate includes: a base substrate 10; a display device formed on a first surface 11 of the base substrate 10 and a first metal connection part 13 extending to an edge of the base substrate 10 (the edges of the base substrate 10 indicated by the dashed lines are formed after the portions of the base substrate 10 corresponding in position to the first surface edge region and the second surface edge region are removed, as shown in FIG. 2g), an electrical signal being provided to the display device through the first metal connection part; a display driver IC formed on a second surface 14 (as shown in FIG. 2j) of the base substrate opposite to the first surface 11 and a second metal connection part 16 extending to the edge of the base substrate 10, the second metal connection part being electrically connected with the display driver IC; and a sidewall metal connection part 30 formed on a sidewall 17 (as shown in FIG. 2j) of the base substrate. The sidewall metal connection part 30 electrically connects the corresponding first metal connection part 13 and second metal connection part 16 such that a drive signal is provided to the display device by the display driver IC.

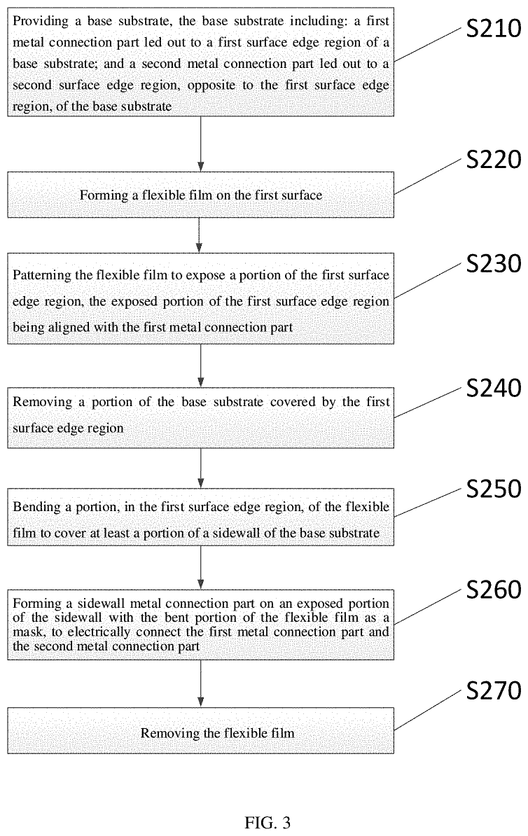

In the above embodiments, an electric connection between the metals on the upper and lower surfaces of the display substrate is taken as an example. However, it would be appreciated by those skilled in the art that the method according to the present disclosure may be used for achieving any electric connection between metals on upper and lower surfaces of a substrate according to the teachings of the present disclosure. Therefore, a further embodiment of the present disclosure provides a metal interconnection method. As shown in FIG. 3, the method includes the following steps.

In a step S210, a base substrate is provided. The base substrate includes: a first metal connection part led out to a first surface edge region of a base substrate; and a second metal connection part led out to a second surface edge region, opposite to the first surface edge region, of the base substrate. An orthogonal projection of the first surface edge region on a plane where the base substrate is located is aligned with an orthogonal projection of the second surface edge region on the plane, and an orthogonal projection of an end, extending to the first surface edge region, of the first metal connection part on the plane is aligned with an orthogonal projection of an end, extending to the second surface edge region, of the second metal connection part on the plane.

In a step S220, a flexible film is formed on the first surface.

In a specific example, the flexible film may be a dry film.

In a step S230, the flexible film is patterned to expose a portion of the first surface edge region. The exposed portion of the first surface edge region is aligned with the first metal connection part.

In a step S240, a portion of the base substrate covered by the first surface edge region is removed.

In a step S250, a portion, in the first surface edge region, of the flexible film is bent to cover at least a portion of a sidewall of the base substrate.

In a step S260, a sidewall metal connection part is formed on an exposed portion of the sidewall with the bent portion of the flexible film as a mask, to electrically connect the first metal connection part and the second metal connection part.

In a step S270, the flexible film is removed.

The metal interconnection method can be used in a case where interconnection of circuits on upper and lower surfaces of a substrate, and is also applicable to a case where a substrate is relative thick and it is difficult to form a via hole in the substrate.

Apparently, the above-mentioned embodiments of the present disclosure are merely examples for clearly explaining the present disclosure, rather than limiting the embodiments of the present disclosure. Those of ordinary skill in the art could also make other different forms of changes or modifications on the basis of the above description, and it is not possible to exhaustively list all embodiments herein. All obvious changes or modifications derived from the technical solutions of the present disclosure are still within the protection scope of the present disclosure.

What is claimed is:

1. A method of constructing a display substrate, the method comprising:
forming, on a first surface of a base substrate, a first metal connection part extending to a first surface edge region, and forming, on a second surface of the base substrate opposite to the first surface, a second metal connection part extending to a second surface edge region, wherein an orthogonal projection of the first surface edge region on a plane where the base substrate is located is aligned with an orthogonal projection of the second surface edge region on the plane, and an orthogonal projection of an end, extending to the first surface edge region, of the first metal connection part on the plane is aligned with an orthogonal projection of an end, extending to the second surface edge region, of the second metal connection part on the plane;
forming a flexible film on the first surface;
patterning the flexible film to expose a portion of the first surface edge region, wherein the exposed portion of the first surface edge region is aligned with the first metal connection part;
removing a portion of the base substrate covered by the first surface edge region;
bending a portion, in the first surface edge region, of the flexible film to cover at least a portion of a sidewall of the base substrate;
forming a sidewall metal connection part on an exposed portion of the sidewall with the bent portion of the flexible film as a mask, to electrically connect the first metal connection part and the second metal connection part; and
removing the flexible film.

2. The method of claim 1, wherein the flexible film comprises a dry film.

3. The method of claim 1, wherein bending the portion, in the first surface edge region, of the flexible film to cover at least the portion of the sidewall of the base substrate comprises:
bending the portion, in the first surface edge region, of the flexible film to cover at least the portion of the sidewall of the base substrate and to extend onto the second surface.

4. The method of claim 2, wherein forming the flexible film on the first surface comprises:
attaching the dry film onto the first surface of the base substrate with a hot pressing roller.

5. The method of claim 2, wherein patterning the flexible film to expose the portion of the first surface edge region comprises:
irradiating the dry film with ultraviolet rays through a mask; and
removing, with a developing solution, a portion of the dry film shielded by the mask, to expose the portion of the first surface edge region aligned with the first metal connection part.

6. The method of claim 2, wherein forming the sidewall metal connection part on the exposed portion of the sidewall with the bent portion of the flexible film as the mask, to electrically connect the first metal connection part and the second metal connection part, comprises:
evaporating a metal on the exposed portion of the sidewall by a magnetron sputtering method with the bent portion of the flexible film as the mask, to form the sidewall metal connection part.

7. The method of claim 2, wherein removing the flexible film comprises:
stripping the dry film by a strongly alkaline solution.

8. The method of claim 1, wherein a display device is disposed on the first surface of the base substrate and a display driver IC is disposed on the second surface of the base substrate opposite to the first surface, such that an electrical signal is provided to the display device through the first metal connection part, and the second metal connection part is electrically connected with the display driver IC.

9. A display substrate, comprising:
a base substrate;
a first metal connection part formed on a first surface of the base substrate and extending to an edge of the base substrate;
a second metal connection part formed on a second surface of the base substrate opposite to the first surface and extending to the edge of the base substrate; and
a sidewall metal connection part formed on a sidewall of the base substrate, wherein the sidewall metal connection part electrically connects the first metal connection part and the second metal connection part.

10. The display substrate of claim 9, further comprising:
a display device formed on the first surface of the base substrate and a display driver IC formed on the second surface of the base substrate opposite to the first surface, wherein an electrical signal is provided to the display device through the first metal connection part, and the second metal connection part is electrically connected with the display driver IC, such that a drive signal is provided to the display device by the display driver IC.

11. A metal interconnection method, comprising:
providing a base substrate, the base substrate comprising: a first metal connection part led out to a first surface edge region of a base substrate; and a second metal connection part led out to a second surface edge region opposite to the first surface edge region, of the base substrate, wherein an orthogonal projection of the first surface edge region on a plane where the base substrate is located is aligned with an orthogonal projection of the second surface edge region on the plane, and an orthogonal projection of an end, extending to the first surface edge region, of the first metal connection part on the plane is aligned with an orthogonal projection of an end, extending to the second surface edge region, of the second metal connection part on the plane;
forming a flexible film on the first surface;
patterning the flexible film to expose a portion of the first surface edge region, wherein the exposed portion of the first surface edge region is aligned with the first metal connection part;
removing a portion of the base substrate covered by the first surface edge region;
bending a portion, in the first surface edge region, of the flexible film to cover at least a portion of a sidewall of the base substrate;
forming a sidewall metal connection part on an exposed portion of the sidewall with the bent portion of the flexible film as a mask, to electrically connect the first metal connection part and the second metal connection part; and
removing the flexible film.

12. The method of claim 11, wherein the flexible film comprises a dry film.
